(19) United States
(12) Patent Application Publication
(10) Pub. No.: US 2008/0181121 A1
(43) Pub. Date: Jul. 31, 2008

(54) Self-Describing Device Interconnections

(76) Inventors: Lee A. Barford, San Jose, CA (US); Stanley T. Jefferson, Palo Alto, CA (US)

Correspondence Address: AGILENT TECHNOLOGIES INC., INTELLECTUAL PROPERTY ADMINISTRATION,LEGAL DEPT., MS BLDG. E P.O. BOX 7599, LOVELAND, CO, 80537, US

(21) Appl. No.: 11/668,402

(22) Filed: Jan. 29, 2007

(51) Int. Cl. G01R 31/08

(52) U.S. Cl. 370/245

(57) ABSTRACT

An apparatus for testing, measuring, and monitoring operation of a set of pieces of equipment, the apparatus comprises a topology network piggybacked on the set of pieces of equipment; and a controller, coupled to the topology network for communication over the network.

### BACKGROUND OF THE INVENTION

The invention relates to the field of electronic equipment, such as test and measurement equipment, and to architectures, networks, etc., made up of pieces of such equipment coupled together.

Currently, the analog and digital external ports of instruments, sensors, and actuators are connected with simple direct electrical and fiber optical connections using cables with connector standards such as BNC, SMA, SMB, SMC, and FC/PC.

The connection topology is potentially useful information for computer-automated measurement. In equipment architectures connected in such conventional manner, the only way to ascertain or verify the connection topology is to manually inspect it. Manual inspection is prone to errors, and consumes significant time. In addition, connecting a number of cables correctly from specifications, instruction manuals, drawings and the like is error-prone. For example, it is easy for a cable to be forgotten and in a complex system its lack will not be noticed by visual inspection. Likewise, it is common for two cables both to be correctly connected at one end, but have their opposite ends swapped. Again, such an occurrence is difficult to find visually.

An automated method potentially could overcome these drawbacks. However, manually inputting the connection topology to a computer database is another error prone, time-consuming task. Additionally, the topology might be changed before the computer database is updated, rendering such manually-entered connection topology obsolete.

### SUMMARY OF THE INVENTION

An apparatus for testing, measuring, and monitoring operation of a set of pieces of equipment, the apparatus comprises a topology network piggybacked on the set of pieces of equipment; and a controller, coupled to the topology network for communication over the network.

Further features and advantages of the present invention, as well as the structure and operation of preferred embodiments of the present invention, are described in detail below with reference to the accompanying exemplary drawings.

### BRIEF DESCRIPTION OF THE DRAWINGS

FIG. 1 is a block diagram of a prior art instrument configuration.

FIG. 2 is a block diagram of an instrument configuration, similar to that of FIG. 1, but incorporating an embodiment of the invention.

### DETAILED DESCRIPTION

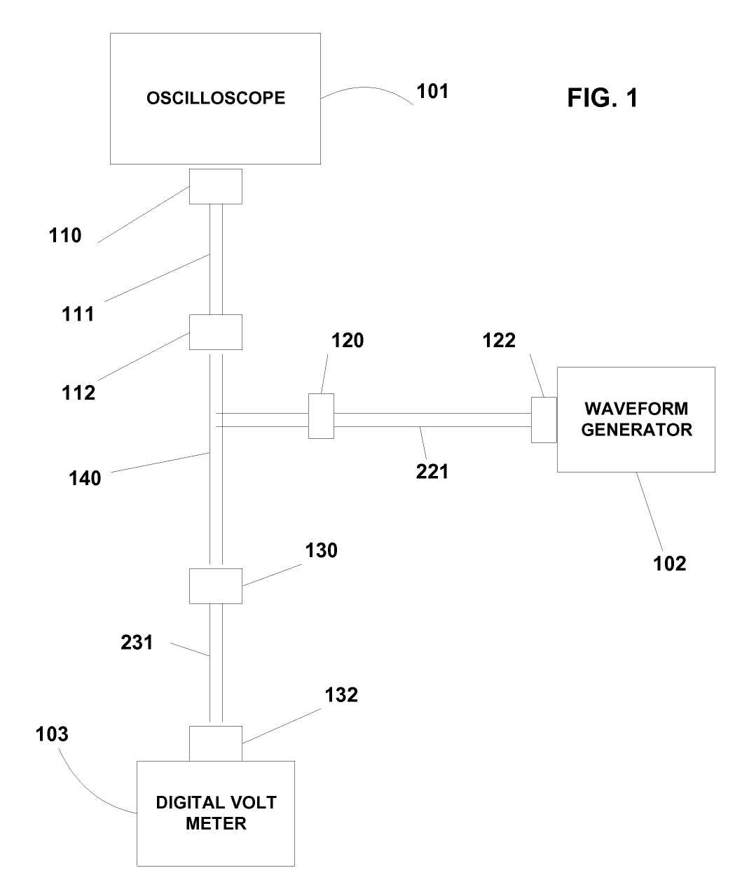

FIG. 1 illustrates a conventional test and measurement instrument configuration, including various pieces of test equipment, in this case shown as an oscilloscope 101, a waveform generator 102, and a digital voltmeter (DVM) 103 (collectively, the “instruments”), coupled together at their interfaces with standard cables such as BNC cables. The respective BNC cables are shown with connectors on either end. Specifically, a first BNC cable 111 has connectors 110 and 112, a second BNC cable 121 has connectors 120 and 122, and a third BNC cable 131 has connectors 130 and 132. A Item 140 is a BNC “T” connector 140 is employed to couple all three of the BNC cables 111, 121, and 131 together, to produce an instrument configuration in which the oscilloscope 101, the waveform generator 102, and the DVM 103 all communicate. In such a configuration, testing and measurement can be performed in a manner known to those skilled in the art.

In an apparatus embodying the invention, a network (for instance, an electrical or fiber optical network) is superimposed, that is “piggybacked”, along the cables, connectors, switches and devices that comprise an electro/optical/mechanical system. Connection points within the electro/optical/mechanical system correspond with respective nodes of the network. Each such node is implemented with digital logic that identifies the connection point, the component to which it belongs, and some capability to identify neighbors of the endpoint on the network. In one embodiment, such implementations are made in digital logic circuitry at each node.

In embodiments of the invention, the network (nodes and connections therebetween) is implemented as an integral part of the components and cables. That is, we might say the appropriate network nodes and connections therebetween are “piggybacked” on the components (instruments, connection cables, etc.) of the electro/optical/mechanical system.

Embodiments of the invention allow the connection topology of a set of devices (e.g. instruments) to be quickly and accurately determined using a computer. The information can be stored in one more computer databases, and utilized by the measurement or control system software. A given device thus has the ability to determine what other devices it is connected to, and the specific input/output connections that are made. Instruments can then use this connection information to configure themselves.

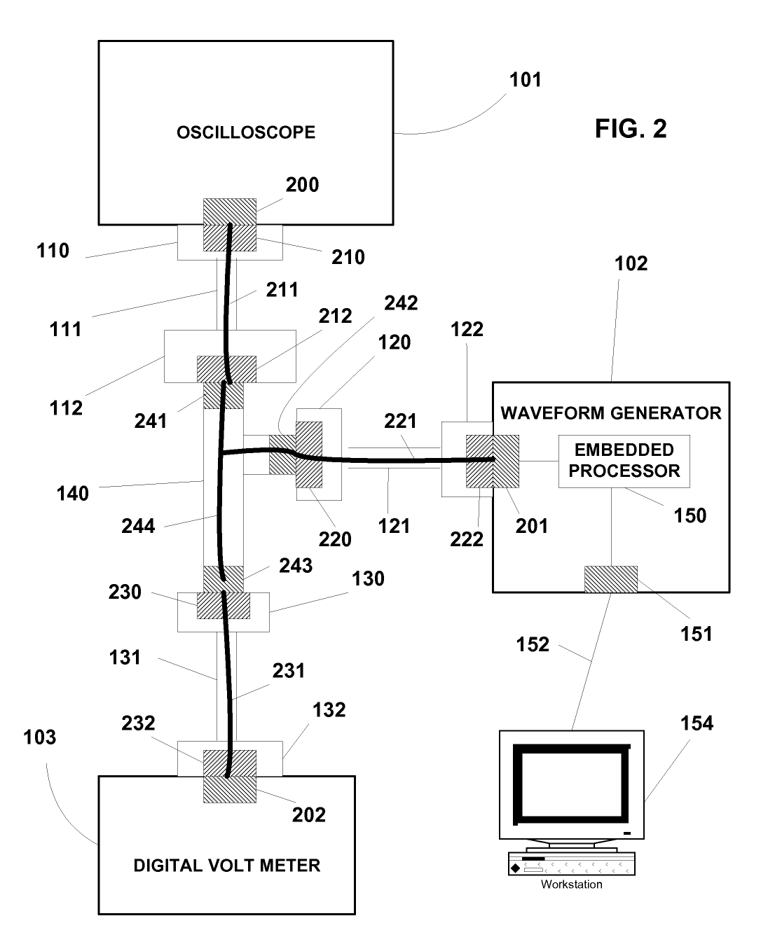

As an example of such an electro/optical/mechanical system embodying the invention, FIG. 2 illustrates a test and measurement configuration functionally similar to that of FIG. 1. The instruments shown in FIG. 2 are coupled for functionality similar to that of the configuration of FIG. 1, using cables and a T connector that are similar to, and numbered the same way as, the equivalent cables, connectors, etc., of FIG. 1.

In this embodiment of the invention, however, there is additionally provided a set of network nodes, piggybacked on the instruments and connectors so as to be superimposed on the configuration topology. The network nodes are shown as cross-hatched rectangles, at respective points in the configuration topology. Network nodes 200, 201, and 202 are provided respectively at the interfaces of the oscilloscope 101, the waveform generator 102, and the DVM 103.

The cables 111, 121, and 131 have network nodes 210, 212, 220, 222, 230, and 232, at their respective connectors 110, 112, 120, 122, 130, and 132. The T connector 140 has three network nodes 241, 242, and 243, one for each “port” of the T.

The network nodes on either end of the cables 111, 121, and 131 are coupled together by means of network cables 211, 221, and 231. A T-configured network cable 244 couples the nodes 241, 242, and 243.

As the test configuration is assembled from the instruments and the cables connecting them, a network is assembled and connected together, comprising the various piggybacked nodes and network cables described above. In an embodiment of the invention, a control and communication apparatus is provided, for communicating over this network to identify the topology formed by the interconnected nodes and network cables.

Additionally, a controller is coupled to the network, to facilitate such communication thereover. In the embodiment of FIG. 2, the node 201 in the waveform generator 102 is connected to an embedded processor 150, which in turn is coupled through an interface 151 to a Local Area Network (LAN) 152. This coupling enables the network topology to be interrogated and communicated back to an operator control apparatus, shown as a computer workstation 154.

A computer model of the network topology may be implemented in a variety of ways, suitably for the operator's particular needs. As one example, the nodes are numbered consecutively, i.e., Port1, Port2, etc. By interrogating the network thus modeled, we might obtain a representation of the following form:
Port 1: Output, waveform generator, SN 123123123
Port 2: End1, BNC cable, SN 343434343
Port 3: End2, BNC cable, SN 343434343
Port 4: End1, BNC T, SN 90909090
Port 5: End2, BNC T, SN 90909090
Port 6: End3, BNC T, SN 90909090
. . .
(Port 1, Port2), (Port2, Port3), (Port3, Port4), (Port4, Port5), (Port4, Port6)

This shows a naming of connection points as ports (e.g. the name Port 1), followed by pairs that yield the graph or topology (i.e., Port 1 is connected to Port 2; Port 2 is connected to Port 3, etc.). Many variations and elaborations of this representation are possible.

Several existing technologies may be employed to implement the network, such as LAN, IEEE 1394 (Firewire), and USB, for example, which have the ability to identify the nodes and discover the node topology.

Devices such as switch matrices, analog crossbar switches, etc., will interact with the network in order to portray the state of the switch, and hence determine the connection topology inside the switch. It isn't necessary to network all the internal switch connections, since the switch connection topology can be derived from the state of the switch matrix.

Embodiments of the invention may be employed in numerous ways. One example of automated use of the connection topology is simply determining if all required connections have been made before running a test. The cable or connector could identify itself and/or its properties so that instruments and system software could determine relevant properties such as impedance and length. This information could be used for calibration or simulation. Having an accurate connection topology stored in a computer database would enable instruments and software to be automatically configured to perform measurement tasks. Cable and component properties and specifications could be ascertained. The parts list for a system could be automatically produced.

The actual connection topology can be automatically compared to the desired connection topology. Technicians or engineers can be notified of any differences by means such as error messages on screens, messages stored to system log files, and the like. The technicians or engineers can then correct any missing or mis-connected cables without having to search for the incorrect cable attachments.

Using a system implemented with components (for instance, pieces of equipment and connectors) having piggybacked topology network nodes and connections, it is possible to build and verify a system out of such components, either for Research and Development (R&D) prototyping or for manufacturing.

Such a method for building and verifying a system comprises assembling a system out of a set of pieces of equipment and connectors, each piece of equipment and connector including topology network nodes and connections superimposed thereon, wherein assembling the system includes coupling the topology network nodes and connections to produce a topology network. The topology network is coupled to a processor having a network analysis application. The processor runs the network analysis application to analyze the topology network. That analysis is then verified against the system to be built and verified.

In such a method, the system may be defined in a model; and the verifying may include verifying the analysis of the topology network against the model. The model may include either a Computer-Aided Design (CAD) diagram, or a design implemented and stored in a database.

The method may also generate a user-readable report including (i) identifiers for the pieces of equipment and the connectors, and (ii) a description of the topology network. Such a report may, for instance, include a parts list.

The invention may also be embodied in a method for diagnosing and fixing a system containing a failed component, the system including a set of pieces of equipment and connectors, each piece of equipment and connector including respective topology network nodes and connections superimposed thereon, the topology network nodes and connections being coupled to produce a topology network. Such a method may include generating a model of the system based on the topology network, identifying the failed component using the model, replacing the failed component and reassembling the system, and verifying the reassembled system using the model.

Although the present invention has been described in detail with reference to particular embodiments, persons possessing ordinary skill in the art to which this invention pertains will appreciate that various modifications and enhancements may be made without departing from the spirit and scope of the claims that follow.

What is claimed is:

1. An apparatus for testing, measuring, and monitoring operation of a set of pieces of equipment, the apparatus comprising:
a topology network superimposed on the set of pieces of equipment; and
a controller, coupled to the topology network for communication over the network.

2. An apparatus as recited in claim 1, wherein:
the set of pieces of equipment includes (i) one or more instruments and (ii) one or more connection cables between the one or more instruments;
the one or more instruments and the one or more connection cables have connection points therebetween; and
the topology network includes (i) nodes at the connection points and (ii) network connections between the nodes.

3. An apparatus as recited in claim 2, wherein the controller includes a processor embedded within one of the one or more instruments.

4. An apparatus as recited in claim 2, wherein the controller includes a workstation.

5. An apparatus as recited in claim 1, wherein the controller communicates over the topology network to identify the topology of the set of pieces of equipment.

6. An apparatus as recited in claim 1, wherein:
the set of pieces of equipment is to undergo a test procedure requiring a predetermined topological configuration; and
the controller communicates over the topology network to determine whether connections required for the predetermined topological configuration have been made.

7. An apparatus as recited in claim 1, wherein the controller communicates over the topology network to determine properties of one of (i) the set of pieces of equipment and (ii) a predetermined one of the pieces of equipment of the set of pieces of equipment.

8. An apparatus as recited in claim 5, further comprising a data store, coupled to the controller for receiving and storing the identified topology of the set of pieces of equipment.

9. An apparatus as recited in claim 5, wherein the controller generates, from the identified topology of the set of pieces of equipment, a parts list for the set of pieces of equipment.

10. A method for building and verifying a system, the method comprising:
assembling a system out of a set of pieces of equipment and connectors, each piece of equipment and connector including topology network nodes and connections superimposed thereon, wherein assembling the system includes coupling the topology network nodes and connections to produce a topology network;
coupling the topology network to a processor having a network analysis application;
running the network analysis application to analyze the topology network; and
verifying the analysis of the topology network against the system to be built and verified.

11. A method as recited in claim 10, wherein:
the system is defined in a model; and
the verifying includes verifying the analysis of the topology network against the model.

12. A method as recited in claim 11, wherein the model includes one of (i) a Computer-Aided Design (CAD) diagram, and (ii) a design implemented and stored in a database.

13. A method as recited in claim 10, further comprising generating a user-readable report including (i) identifiers for the pieces of equipment and the connectors, and (ii) a description of the topology network.

14. A method for diagnosing and fixing a system containing a failed component, the system including a set of pieces of equipment and connectors, each piece of equipment and connector including respective topology network nodes and connections superimposed thereon, the topology network nodes and connections being coupled to produce a topology network; the method comprising:
generating a model of the system based on the topology network;
identifying the failed component using the model,
replacing the failed component and reassembling the system; and
verifying the reassembled system using the model.
